(19) United States
(12) Patent Application Publication
(10) Pub. No.: US 2025/0180771 A1
(43) Pub. Date: Jun. 5, 2025

(54) MOISTURE DETECTION CIRCUITS AND METHODS FOR SERIAL BUS CONNECTORS

(71) Applicants: SILICON MITUS, INC., Seongnam-Si (KR); Hangzhou Silicon-Magic Semiconductor Technology Co., Ltd., Hangzhou City (CN)

(72) Inventors: Hyung Gu Park, Suwon-Si (KR); Jun Ho Moon, Seongnam-Si (KR); Sang Hyun Cha, Seoul (KR); Il Kwon Chang, Goyang-Si (KR)

(73) Assignees: SILICON MITUS, INC., Seongnam-Si (KR); Hangzhou Silicon-Magic Semiconductor Technology Co., Ltd., Hangzhou City (CN)

(21) Appl. No.: 18/827,450

(22) Filed: Sep. 6, 2024

(30) Foreign Application Priority Data
Nov. 30, 2023 (KR) 10-2023-0171339

(51) Int. Cl. G01V 3/02

(52) U.S. Cl. CPC G01V 3/02

(57) ABSTRACT

A moisture detection circuit for serial bus connectors includes: a current digital-to-analog converter that receives a first digital signal indicating a current reference value and outputs an analog current with a magnitude corresponding to that of the first digital signal to a terminal of the serial bus connector; a voltage digital-to-analog converter that receives a second digital signal indicating a voltage reference value and outputs an analog voltage with a magnitude corresponding to that of the second digital signal; a comparator that compares a voltage of the terminal with a voltage output by the voltage digital-to-analog converter; and a controller that provides a first digital signal indicating the current reference value to the current digital-to-analog converter and provides a second digital signal indicating the voltage reference value to the voltage digital-to-analog converter to determine presence or absence of moisture adhering to the terminal based on comparison results of the comparator.

### CROSS-REFERENCE TO RELATED APPLICATIONS

This application claims the benefit of Korea Patent Application No. 10-2023-0171339, filed on Nov. 30, 2023, which is incorporated herein by reference for all purposes as if fully set forth herein.

### TECHNICAL FIELD

The present disclosure related to a moisture detection circuit and its methods for detecting moisture in a serial bus connector such as USB-C.

### BACKGROUND

Some electronic devices supply power or perform communications with external electronic devices through a cable connected to a connector. When foreign matters such as moisture enter a connector, it may cause some terminals to be short-circuited, corroded, or damaged, and in some cases, it may lead to excessive power consumption. Thus, it is necessary to detect the ingress of moisture into a connector. In addition, it is desirable to be able to determine whether a normal accessory is attached, and it should not be confused with a case where a normal accessory is attached when detecting the ingress of moisture into a connector.

### SUMMARY

The present disclosure provides a circuit and a method to determine the cases where there is a normal accessory or moisture adhered to a serial bus connector with a simple structure.

The present disclosure reduces excessive power consumption and the area occupied on the semiconductor chip in implementing a circuit that can determine whether a serial bus connector is adhered by moisture or normal accessories.

In one aspect of the present disclosure, a moisture detection circuit for serial bus connectors includes a current digital-to-analog converter that receives a first digital signal indicating a current reference value and outputs an analog current with a magnitude that corresponds to that of the first digital signal to a terminal of the serial bus connector; a voltage digital-to-analog converter that receives a second digital signal indicating a voltage reference value and outputs an analog voltage with a magnitude that corresponds to that of the second digital signal; a comparator that compares a voltage of the terminal of the serial bus connectors with a voltage output by the voltage digital-to-analog converter; and a controller that provides a first digital signal indicating the current reference value to the current digital-to-analog converter and provides a second digital signal indicating the voltage reference value to the voltage digital-to-analog converter, and determines presence or absence of moisture adhering to the terminal based on comparison results of the comparator.

In the moisture detection circuit for serial bus connectors, the current digital-to-analog converter outputs a current of a first current reference value in the first period and the second period and outputs a current of a second current reference value in the third period and the fourth period; the voltage digital-to-analog converter outputs a voltage of a first voltage reference value in the first period and the third period and outputs a voltage of a second reference value in the second period and the fourth period; the comparator compares a voltage output by the voltage digital-to-analog converter and the terminal voltage in each of the first period to fourth period; and the controller determines presence or absence of moisture adhering to the terminal of the serial bus connectors based on the comparison results of the comparator in the first to fourth periods. The time order of the first to fourth periods can be arbitrary.

In the moisture detection circuit for serial bus connectors, when following conditions are met, the controller determines that the terminal of the serial bus connectors is adhered by moisture: the first current reference value is less than the second current reference value; the first voltage reference value is greater than the second voltage reference value; the terminal voltage is less than the first voltage reference value in the first period; the terminal voltage is greater than the second voltage reference value in the second period; the terminal voltage is greater than the first voltage reference value in the third period; and the terminal voltage is greater than the second voltage reference value in the fourth period.

In the moisture detection circuit for serial bus connectors, when following conditions are met, the controller determines that a normal accessory is mounted on the terminal of the serial bus connectors: the first current reference value is less than the second current reference value; the first voltage reference value is greater than the second voltage reference value; the terminal voltage is less than the first voltage reference value in the first period; the terminal voltage is less than the second voltage reference value in the second period; the terminal voltage is less than the first voltage reference value in the third period; the terminal voltage is greater than the second voltage reference value in the fourth period.

In the moisture detection circuit for serial bus connectors, the current digital-to-analog converter may be a 1-bit digital-to-analog converter capable of selectively outputting a current of a first current reference value and a current of a second current reference value, and the voltage digital-to-analog converter may be a 1-bit digital-to-analog converter capable of selectively outputting a voltage of a first voltage reference value and a voltage of a second voltage reference value.

In the moisture detection circuit for serial bus connectors, it may further include an edge detector that detects a rising or falling edge of a signal provided to the terminal by a host controller to create an enable signal, and provides the enable signal to the controller.

In the moisture detection circuit for serial bus connectors, the controller may start the moisture detection operation based on the enable signal output by the edge detector.

In the moisture detection circuit for serial bus connectors, the controller may open a switch that connects the terminal with a host controller when it is determined that the terminal is adhered by moisture.

One aspect of the present disclosure relates to a method of detecting moisture for serial bus connectors comprising: a first period comparison step that compares a terminal voltage and a first voltage reference value while applying a current of a first current reference value to a terminal of the serial bus connectors; a second period comparison step that compares the terminal voltage and the second voltage reference value while applying a current of the first current reference value to the terminal of the serial bus connectors; a third period comparison step that compares the terminal voltage and the first voltage reference value while applying a current of the second current reference value to the terminal of the serial bus connectors; a fourth period comparison step that compares the terminal voltage and the second voltage reference value while applying a current of the second current reference value to the terminal of the serial bus connectors; and a step that determines whether the terminal is adhered by moisture based on the comparison result of the first period comparison step to fourth period comparison step.

In the moisture detection circuit for serial bus connectors, when following conditions are met, the controller determines that the terminal of the serial bus connectors is adhered by moisture: the first current reference value is less than the second current reference value; the first voltage reference value is greater than the second voltage reference value; the terminal voltage is less than the first voltage reference value in the first period comparison step; the terminal voltage is greater than the second voltage reference value in the second period comparison step; the terminal voltage is greater than the first voltage reference value in the third period comparison step; and the terminal voltage is greater than the second voltage reference value in the fourth period comparison step.

In the moisture detection circuit for serial bus connectors, when following conditions are met, the controller determines that a normal accessory is mounted on the terminal the terminal of the serial bus connectors: the first current reference value is less than the second current reference value; the first voltage reference value is greater than the second voltage reference value; the terminal voltage is less than the first voltage reference value in the first period comparison step; the terminal voltage is less than the second voltage reference value in the second period comparison step; the terminal voltage is less than the first voltage reference value in the third period comparison step; and the terminal voltage is greater than the second voltage reference value in the fourth period comparison step.

In the moisture detection circuit for serial bus connectors, the moisture detection method may be initiated based on a rising edge or falling edge of a signal provided by a host controller to a terminal of the serial bus connector.

According to one or more embodiments of the present disclosure, it is possible to determine whether a serial bus connector is adhered by moisture or normal accessories while implementing a simple circuit.

According to one or more embodiments of the present disclosure, it is possible to reduce the power consumption and the area occupied on the semiconductor chip when implementing a circuit that can determine whether a serial bus connector is adhered by moisture or normal accessories.

The effects of the present disclosure are not limited to the effects described above, and various effects not mentioned herein may be included in the present specification.

### BRIEF DESCRIPTION OF THE DRAWINGS

The accompanying drawings, which are included to provide a further understanding of the disclosure and are incorporated in and constitute a part of the disclosure, illustrate embodiments of the disclosure and together with the description serve to explain the principle of the disclosure.

FIG. 1 depicts a block diagram of a moisture detection circuit according to one or more embodiments of the present disclosure.

FIG. 2 is a waveform diagram illustrating an operation of detecting an event when a connector is adhered by moisture according to one or more embodiments of the present disclosure.

FIG. 3 is a waveform diagram illustrating an operation of detecting an event when a normal accessory is mounted on a connector.

FIG. 4 depicts a moisture detection method according to one or more embodiments of the present disclosure.

### DETAILED DESCRIPTION

Hereinafter, some embodiments of the present disclosure will be described in detail with reference to exemplary drawings. It should be noted that the same constituent elements are denoted by the corresponding reference symbols even if they are shown in different drawings in adding reference numerals to the constituent elements of the drawings. In addition, in describing the present disclosure, a detailed description of known functions and configurations incorporated herein will be omitted when it may make the subject matter of the present disclosure rather unclear.

Furthermore, in describing the constituent elements of the present disclosure, the terms A, B, (a), (b), and the like can be used. These terms are intended to distinguish the constituent elements from other constituent elements, and the terms do not limit the nature, order or order of the constituent elements. When a component is described as being “connected”, “comprising”, or “configured” to another component, the component may be directly connected or connected to the other component, it is to be understood that the element may be “connected”, “comprising”, or “configured”.

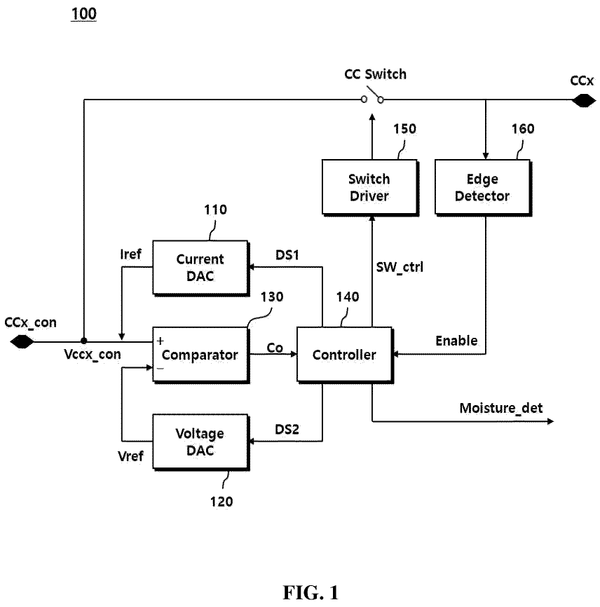

FIG. 1 depicts a block diagram of a moisture detection circuit according to one or more embodiments of the present disclosure.

Referring to FIG. 1, a moisture detection circuit 100 can detect whether a connector is adhered by moisture or by a normal accessory by being connected to a wire that connects a connector (not shown in this figure) for serial communication and a host controller (not shown in this figure). The connector for serial communication, for example, may be a connector for the type-C Universal Serial Bus (USB). For example, as depicted in FIG. 1, a moisture detection circuit 100 may operate by being connected to a wire connecting a CC (configuration Channel) terminal (CCx) of a host controller and its corresponding CC terminal (CCx_con) of a USB-C connector. In the following, a case where a moisture detection circuit 100 is connected to a CC terminal wiring of an USB-C connector is used to describe an operation of a moisture detection circuit 100; however, a moisture detection circuit 100 of the present disclosure does not necessarily have to be connected to a CC terminal wiring of an USB-C connector.

A moisture detection circuit 100 may selectively include at least a part of the components shown in FIG. 1 such as a current digital-to-analog converter 110, a voltage digital-to-analog converter 120, a comparator 130, a controller 140, a switch driver 150, and an edge detector 160, if necessary. It is obvious that a moisture detection circuit 100 may include other components, if necessary, in addition to ones shown in FIG. 1.

A current digital-to-analog converter 110 can output a reference current (Iref) to a connector's CC terminal (CCx_con). Specifically, a current digital-to-analog converter 110 can receive a DS1 indicating a current reference value from a controller 140, and output a reference current (Iref) in the form of analog with a magnitude that corresponds to that of a DS1 to a connector's CC terminal (CCx_con).

A voltage digital-to-analog converter 120 can output a reference voltage (Vref) to a comparator 130. Specifically, a voltage digital-to-analog converter 120 can receive a DS2 indicating a voltage reference value from a controller 140, and output a reference voltage (Vref) in the form of analog with a magnitude that corresponds to that of a DS2.

A comparator 130 can compare a voltage (Vccx_con) of a connector CC terminal (CCx_con) with a voltage (Vref) output by a voltage digital-to-analog converter 120, and provide that result signal (Co) to a controller 140. A current (Iref) output by a current digital-to-analog converter 110 creates a voltage (Vccx_con) at a connector CC terminal. The magnitude of this voltage (Vccx_con) may vary depending on whether a connector CC terminal (CCx_con) is adhered by moisture or a normal accessory. A voltage digital-to-analog converter 120 outputs a reference voltage (Vref) that can distinguish a case where it is adhered by moisture from a case where a normal accessory is mounted, corresponding to a current (Iref) output by a current digital-to-analog converter 110, and a comparator 130 can determine types of external objects that are attached to a connector CC terminal (CCx_con) by comparing a reference voltage (Vref) output by a voltage digital-to-analog converter 120 with a voltage (Vccx_con) that is actually formed on a connector CC terminal.

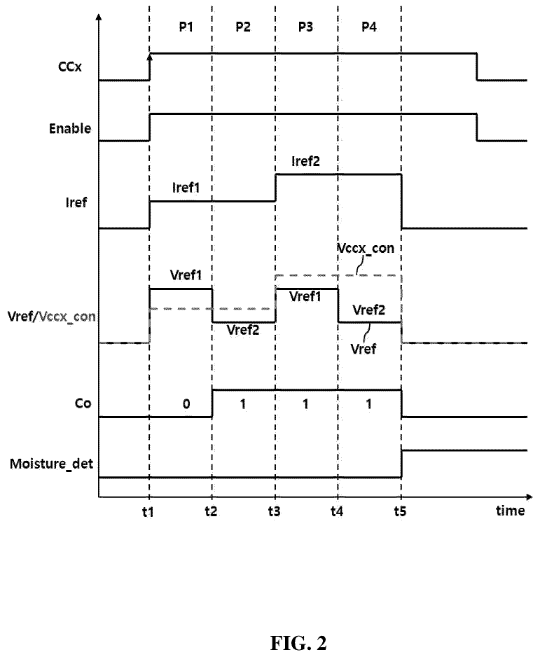

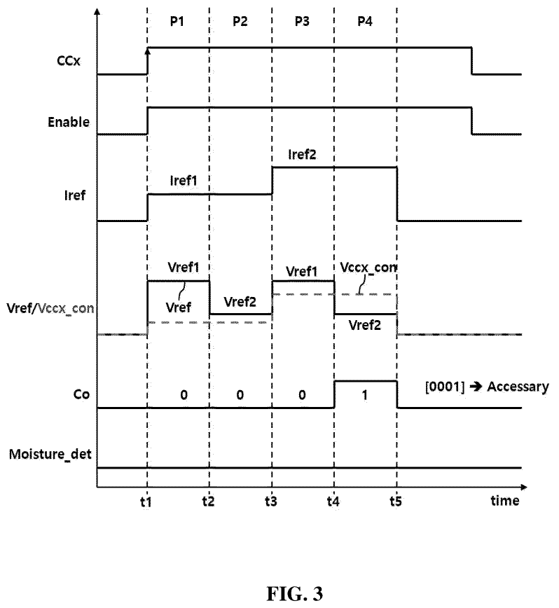

At this time, using a reference current (Iref) and a reference voltage (Vref) may not be sufficient for determining whether there is moisture or a normal accessory attached. Therefore, as described with reference to FIGS. 2 and 3 below, it may be possible to determine whether there is moisture or a normal accessory attached by comparing multiple reference voltages (Vref) and voltages of connector CC terminals (Vccx_con) while applying multiple reference currents (Iref).

A controller 140 provides a DS1 indicating a current reference value to a current digital-to-analog converter 110; provides a DS2 indicating a voltage reference value to a voltage digital-to-analog converter 120; and can determine whether there is moisture or a normal accessory attached to a connector CC terminal (CCx_con) based on the comparison results of a comparator 130. A specific method of determining whether there is moisture or a normal accessory attached to a CC terminal of a connector (CCx_con) will be described in detail below with reference to FIGS. 2 and 3.

When the moisture ingress is detected on the CC terminal of a connector (CCx_con), a controller 140 can break a connection between a host controller and a connector. To this end, a terminal connection switch (CC Switch) is disposed between a CC terminal of a connector (CCx_con) and a CC terminal of a host controller (CCx), and a controller 140 can drive a terminal connection switch (CC Switch) by providing a switch controller signal (SW_ctrl) to a switch driver 150. When the moisture is detected on a CC terminal of a connector (CCx_con), a controller 140 can break a connection between a CC terminal of a connector (CCx_con) and a CC terminal of a host controller (CCx) by opening the terminal connection switch (CC Switch) through a switch driver 150.

In addition, when the moisture ingress is detected on a CC terminal of a connector (CCx_con), a controller 140 can provide a signal (Moisture_det) indicating that there is moisture detected on a CC terminal of a connector (CCx_con) outside (for instance, a host controller).

An edge detector 160 can create an enable signal (Enable) by detecting a rising edge or falling edge of a signal provided to a CC terminal (CCx) by a host controller, and can provide an enable signal (Enable) to a controller 140. A controller 140 can start the moisture detection operation based on an enable signal (Enable) output from an edge detector 160. In other words, a controller 140 can be synchronized with an enable signal (Enable) output by an edge detector 160 to cause a current digital-to-analog converter 110 to output a reference current (Iref), and can cause a voltage digital-to-analog converter 120 to output a reference voltage (Vref).

FIG. 2 is a waveform diagram depicting an operation for detecting moisture on a connector according to one or more embodiments of the disclosure.

Referring to the example of FIG. 2, a voltage of a host controller's CC terminal (CCx) can change from ‘low’ to ‘high’ at time t1. An edge detector 160 can detect a rising edge of a voltage on a host controller's CC terminal (CCx) and can change an enable signal (Enable) from ‘low’ to ‘high’. A controller 140 can start the moisture detection operation based on the enable signal (Enable) output by an edge detector 160. In other words, a controller 140 can be synchronized at the time when an enable signal (Enable) output by an edge detector 160 is changed from ‘low’ to ‘high’ so that a current digital-to-analog converter 110 outputs a reference current (Iref) and a voltage digital-to-analog converter 120 to output a reference voltage (Vref).

When the moisture detection operation starts, a current digital-to-analog converter 110 can output a current of an Iref1 in a first period P1 and a second period P2, and can output a Iref2 in a third period P3 and a fourth period P4. A current reference value provided by a current digital-to-analog converter 110 for each period, as described above, may be set based on a DS1 provided by a controller 140. At this time, the first period P1 is the interval between t1 and t2, the second period P2 is the interval between t2 and t3, the third period P3 is the interval between t3 and t4, and the fourth period P4 is the interval between t4 and t5.

A voltage digital-to-analog converter 120 can output a voltage of a Vref1 in the first period P1 and third period P3, and output a voltage of a Vref2 in the second period P2 and the fourth period P4. A voltage reference value provided by a voltage digital-to-analog converter 120, as described above, may be set based on a DS2 provided by a controller 140.

A comparator 130 can compare a voltage (Vref) output by a voltage digital-to-analog converter 120 with a CC terminal voltage of a connector (Vccx_con) in each of the first period to the fourth period (P1˜P4), and can provide the result signal (Co) to a controller 140.

A controller 140 can determine whether or not a CC terminal of a connector (CCx_con) is adhered by moisture or a normal accessory based on the comparison result (Co) of a comparator 130 in the first period to fourth period (P1˜P4).

In accordance with one or more embodiments of the disclosure, as depicted in FIG. 2, a Iref1 may be less than a Iref2 while a Vref1 may be greater than Vref2. In this case, when the following conditions are met, a controller 140 can determine that a terminal (CCx_con) is adhered by moisture: a terminal voltage (Vccx_con) is less than a Vref1 in the first period P1; a terminal voltage (Vccx_con) is greater than a Vref2 in the second period P2; a terminal voltage (Vccx_con) is greater than a Vref1 in the third period P3; a terminal voltage (Vccx_con) is greater than a Vref2 in the fourth period P4. In other words, when a comparison result (Co) of a comparator 130 indicates the code of [0111] in the order in the first period P1 to the fourth period P4, a controller 140 can determine that there is moisture adhered to a terminal (CCx_con). When it is determined that there is moisture adhered to a terminal (CCx_con), a controller 140 can change the moisture detection signal (Moisture_det) from ‘low’ to ‘high’ to be output.

At this time, a time order of the first period P1 to the fourth period P4 may be arbitrary. That is, it is illustrated to proceed in the order to the first period P1, the second period P2, the third period P3, and the fourth period P4 in FIG. 2, however, for example, it can proceed in the order of the first period P1, the third period P3, the second period P2, and fourth period P4. Two voltage reference values (Vref1 and Vref20) are compared with respect to a Iref2 in the third period P3 and the fourth period P4 thereby comparing four situations in the four periods (P1˜P4). When comparisons for these four situations that could be performed, the order may be changed. If the time order of the four periods is changed, the code of an output signal (Co) of a comparator that is determined to have moisture adhered will also be changed accordingly. For example, when it proceeds in following order: the second period P2, the firth period P1, the third period P3, the fourth period P4, the code of an output signal (Co) of a comparator that is determined to have moisture attached will be [1011].

According to one or more embodiments of the disclosure, a current digital-to-analog converter 110 may be a 1-bit digital-to-analog converter that can selectively output a current of an Iref1 and a current of an Iref2. A voltage digital-to-analog converter 120 may be a 1-bit digital-to-analog converter that can selectively output a voltage of a Vref1 and a voltage of a Vref2. In this case, as illustrated in FIG. 2, a comparison of four situations can be performed, and presence or absence of moisture can be determined based on the results. If the resolution of a current digital-to-analog converter 110 and a voltage digital-to-analog converter 120 is increased, comparisons on more sufficient reference currents and reference voltages should be carried out to have a more precise determination result.

In FIG. 2, ‘low’ and ‘high’ of each signal are just an example for convenience of description so it is obvious that ‘low’ and ‘high’ may be applied in opposite or different ways while operating on the same principle.

FIG. 3 is a waveform diagram depicting an operation of detecting a case where a normal accessory is mounted on a connector according to one or more embodiments of the disclosure.

Referring to FIG. 3, the same can be applied to the generation of an enable signal (Enable) by an edge detector 160, the generation of an Iref by a current digital-to-analog converter 110, and the generation of a Vref by a voltage digital-to-analog converter 120 as described with reference to FIG. 2. FIG. 3 is different from FIG. 2 in that it presents a method of determining a case where a normal accessory is mounted on a CC terminal of a connector (CCx_con).

In accordance with one or more embodiments of the disclosure, a current digital-to-analog converter 110 may output a current of an Iref1 in the first period P1 and the second period P2, and output a current of an Iref2 in the third period P3 and the fourth period P4. A voltage digital-to-analog converter 120 may output a voltage of a Vref1 in the first period P1 and the third period P3, and output a voltage of a Vref2 in the second period P2 and the fourth period P4.

At this time, an Iref1 may be less than an Iref2 and a Vref1 may be greater than a Vref2. In this case, a controller 140 can determine that a normal accessory is mounted on a terminal (CCx_con) when the following conditions are met: a terminal voltage (Vccx_con) is less than a Vref1 in the first period P1; a terminal voltage (Vccx_con) is less than a Vref2 in the second period P2; a terminal voltage (Vccx_con) is less than a Vref1 in the third period P3; a terminal voltage (Vccx_con) is greater than a Vref2 in the P4.

That is, when the comparison result (Co) of a comparator 130 outputs the value of [0001] in the first period P1 to fourth period P4 in order, a controller 140 can determine that a normal accessory is mounted on a terminal (CCx_con). As mentioned above, the order of the first period P1 to the fourth period P4 may be changed, and in this case, the code of a comparison result (Co) of a comparator 130 that is determined to have a normal accessory installed will also be changed.

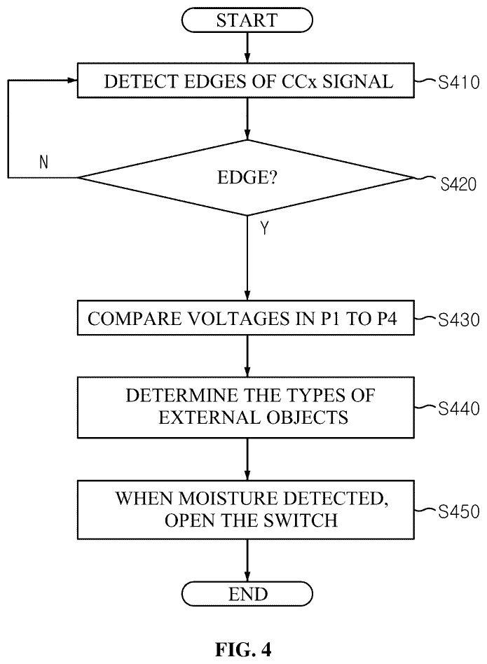

FIG. 4 depicts a moisture detection method according to one or more embodiments of the present disclosure.

The moisture detection method depicted in FIG. 4, for example, may be performed by a moisture detection circuit for a serial bus connector described with reference to FIG. 1.

First, it is possible to detect a CCx signal (S410), which is provided by a host controller to a terminal of a serial bus connector, and determine whether a rising edge or falling edge occurs in the CCx signal (S420). If a rising edge or falling edge occurs in a CCx signal, it enters into the step S430, and it is possible to start comparing voltages in order to determine the adhesion of foreign matters. If no rising edges or falling edges occur in a CCx signal, the process returns to the step S410 and repeats the edge detection of a CCx signal.

Next, voltage comparisons may be performed in the four periods (P1 ˜P4) illustratively described with reference to FIG. 2. For example, the following comparison steps will be performed sequentially: a first period comparison step that compares a terminal voltage with a first voltage reference value while applying a current of a first current reference value to the terminal of the serial bus connectors; a second period comparison step that compares a terminal voltage with a second voltage reference value while applying a current of a first current reference value to the terminal of the serial bus connectors; a third period comparison step that compares a terminal voltage with a first voltage reference value while applying a current of a second current reference value to the terminal of the serial bus connectors; and a fourth period comparison step that compares a terminal voltage with a second voltage reference value to the terminal of the serial bus connectors.

Next, it is possible to determine whether there is moisture or a normal accessory adhered to a terminal based on the comparison results in a first period comparison step through a fourth period comparison step (S440).

For example, a first current reference value may be set to be less than a second current reference value, and a first voltage reference value may be set to be greater than a second voltage reference value. In this case, when following conditions are met, it is determined that there is moisture adhered to a terminal: a terminal voltage is less than a first voltage reference value in the first period comparison step; a terminal voltage is greater than a second voltage reference value in the second period comparison step; a terminal voltage is greater than a first voltage reference value in the third period comparison step; and a terminal voltage is greater than a second voltage reference value in the fourth period comparison step.

For example, a first current reference value may be set to be less than a second current reference value, and a first voltage reference value may be set to be greater than a second voltage reference value. In this case, when following conditions are met, it is determined that there is a normal accessory adhered to a terminal: a terminal voltage is smaller than a first voltage reference value in the first period comparison step; a terminal voltage is smaller than a second voltage reference value in the second period comparison step; a terminal voltage is smaller than a first voltage reference value in the third period comparison step; and a terminal voltage is greater than a second voltage reference value in the fourth period comparison step.

At this time, it is easily understood that the order of the first to fourth period comparison steps may be changed while operating on the same principle as described above.

When it is determined that there is moisture adhered to a terminal in the step S440, a switch connecting a terminal of a serial bus connector and a terminal of a host controller may be open (S450).

In some of the foregoing embodiments, at least a part of the following components may be implemented on a single semiconductor chip: a current digital-to-analog converter 110; voltage digital-to-analog converter 120; comparator 130; controller 140; switch driver 150; and edge detector 160. In this case, each component can be distinguished by its function regardless of its spatial separation.

In one or more embodiments shown in FIGS. 2 and 3, only two 1-bit digital-to-analog converters and a comparator are used in order to compare the voltages of four situations divided into four periods. If a comparator is mainly used, rather than using a digital-to-analog converter, in order to perform such functions, a large number of comparators and complex circuitry should be required. One or more embodiments of the present disclosure are able to implement this function by only using a comparator and two low-resolution (only 1-bit) digital-to-analog converters. Since a digital-to-analog converter with a 1-bit resolution can be implemented in a very small area on a semiconductor chip, it provides not only small occupied chip area and low cost, but also low power consumption, compared to using multiple comparators. According to one or more embodiments, it may be advantageous to increase the resolution of a digital-to-analog converter. For example, when implementing 2-bit resolution for a current digital-to-analog converter and a voltage digital-to-analog converter respectively, it is possible to perform the comparison in the 16 periods where four reference current values and four reference voltage values are combined, which leads to the improvement in the judgment accuracy of various external objects. If these functions are implemented mainly using comparators rather than using digital-to-analog converters, the structure will become very complicated.

Terms such as “include,” “comprise,” or “have” herein mean that the corresponding components may be included, unless specifically stated to the contrary, and thus do not exclude other components. Rather, it should be interpreted as being able to include other components. All terms, including technical and scientific, unless otherwise defined, have the same meaning as generally understood by a person of ordinary skill in the technical field to which the present disclosure pertains. Commonly used terms, such as terms defined in a dictionary, should be interpreted as consistent with the meaning in the context of the related technology, and should not be interpreted in an idealized or overly formal sense unless explicitly defined in the present disclosure.

The above description is merely illustrative of the technical idea of the present disclosure, and those of ordinary skill in the technical field to which the present disclosure belongs will be able to make various modifications and variations without departing from the essential characteristics of the present disclosure. Accordingly, embodiments herein are not intended to limit the technical idea of the present disclosure, but to explain the technical idea, and the scope of the technical idea of the present disclosure is not limited by these embodiments. The scope of protection of this disclosure should be interpreted by the following claims, and all technical ideas within the scope equivalent thereto should be construed as being included in the scope of the present disclosure.

### DESCRIPTION OF THE REFERENCE NUMBERS FOR THE MAIN PARTS OF THE DRAWINGS

110: current digital-to-analog converter
120: voltage digital-to-analog converter
130: comparator
140: controller
150: switch driver
160: edge detector
Iref: current reference
Iref1: first current reference value
Iref2: second current reference value
Vref: voltage reference
Vref1: first voltage reference value
Vref2: second voltage reference value
DS1: first digital signal
DS2: second digital signal
Co: comparator output signal
SW_ctrl: switch control signal
Enable: enable signal

What is claimed is:

1. A moisture detection circuit for serial bus connectors, comprising:
a current digital-to-analog converter that receives a first digital signal indicating a current reference value and outputs an analog current with a magnitude that corresponds to that of the first digital signal to a terminal of the serial bus connectors;
a voltage digital-to-analog converter that receives a second digital signal indicating a voltage reference value and outputs an analog voltage with a magnitude that corresponds to that of the second digital signal;
a comparator that compares a voltage of the terminal of the serial bus connectors with a voltage output by the voltage digital-to-analog converter; and
a controller that provides a first digital signal indicating the current reference value to the current digital-to-analog converter and provides a second digital signal indicating the voltage reference value to the voltage digital-to-analog converter to determine presence or absence of moisture adhering to the terminal based on comparison results of the comparator.

2. The moisture detection circuit for serial bus connectors according to claim 1,
wherein the current digital-to-analog converter outputs a current of a first current reference value in a first period of time P1 and a second period of time P2, and outputs a current of a second current reference value in a third period of time P3 and a fourth period of time P4;
the voltage digital-to-analog converter outputs a voltage of a first voltage reference value in the first period P1 and the third period P3, and a voltage of a second voltage reference value in the second period P2 and fourth period P4;
the comparator compares the terminal voltage with the voltage output by the voltage digital-to-analog converter in each of the first period P1 to fourth period P4; and
the controller determines whether there is moisture adhered to the terminal of the serial bus connectors based on the comparison result of the comparator in the first period P1 to fourth period P4;
wherein a time order of the first period P1 to the fourth period P4 is arbitrary.

3. The moisture detection circuit for serial bus connectors according to claim 2,
wherein the controller determines that the terminal is adhered by moisture when following conditions are met:
the first current reference value is less than the second current reference value;
the first voltage reference value is greater than the second voltage reference value;
the terminal voltage is less than the first voltage reference value in the first period P1;
the terminal voltage is greater than the second voltage reference value in the second period P2;
the terminal voltage is greater than the first voltage reference value in the third period P3; and
the terminal voltage is greater than the second voltage reference value in the fourth period P4.

4. The moisture detection circuit for serial bus connectors according to claim 2,
wherein the controller determines that a normal accessory is mounted on the terminal when following conditions are met:
the first current reference value is less than the second current reference value;
the first voltage reference value is greater than the second voltage reference value;
the terminal voltage is less than the first voltage reference value in the first period P1;
the terminal voltage is less than the second voltage reference value in the second period P2;
the terminal voltage is less than the first voltage reference value in the third period P3; and
the terminal voltage is greater than the second voltage reference value in the fourth period P4.

5. The moisture detection circuit for serial bus connectors according to claim 1, wherein
the current digital-to-analog converter is a 1-bit digital-to-analog converter capable of selectively outputting a current of a first current reference value and a current of a second current reference value; and
the voltage digital-to-analog converter is a 1-bit digital-to-analog converter capable of selectively outputting a voltage of a first voltage reference value and a voltage of a second voltage reference value.

6. The moisture detection circuit for serial bus connectors according to claim 1,
wherein the moisture detection circuit further includes an edge detector that detects a rising or falling edge of a signal provided to the terminal by a host controller to create an enable signal, and provides the enable signal to the controller.

7. The moisture detection circuit for serial bus connectors according to claim 6,
wherein the controller starts moisture detection operation based on the enable signal output by the edge detector.

8. The moisture detection circuit for serial bus connectors according to claim 1,
wherein the controller opens a switch that connects the terminal with a host controller when it is determined that the terminal is adhered by moisture.

9. A moisture detection method by a moisture detection circuit for serial bus connectors, comprising:
a first period comparison step of comparing a terminal voltage and a first voltage reference value while applying a current of a first current reference value to a terminal of the serial bus connectors;
a second period comparison step of comparing the terminal voltage and a second voltage reference value while applying a current of the first current reference value to the terminal of the serial bus connectors;
a third period comparison step of comparing the terminal voltage and the first voltage reference value while applying a current of a second current reference value to the terminal of the serial bus connectors;
a fourth period comparison step of comparing the terminal voltage and the second voltage reference value while applying a current of the second current reference value to the terminal of the serial bus connectors; and
determining whether the terminal is adhered by moisture based on comparison results from the first period comparison step to fourth period comparison step.

10. The moisture detection method by a moisture detection circuit for serial bus connectors according to claim 9, further comprises:
determining that the terminal of the serial bus connectors is adhered by moisture when following conditions are met:
the first current reference value is less than the second current reference value;
the first voltage reference value is greater than the second voltage reference value;
the terminal voltage is less than the first voltage reference value in the first period comparison step;
the terminal voltage is greater than the second voltage reference value in the second period comparison step;
the terminal voltage is greater than the first voltage reference value in the third period comparison step; and
the terminal voltage is greater than the second voltage reference value in the fourth period comparison step.

11. The moisture detection method by a moisture detection circuit for serial bus connectors according to claim 9, further comprises:
determining that a normal accessory is mounted on the terminal of the serial bus connectors when following conditions are met:
the first current reference value is less than the second current reference value;
the first voltage reference value is greater than the second voltage reference value;
the terminal voltage is less than the first voltage reference value in the first period comparison step;
the terminal voltage is less than the second voltage reference value in the second period comparison step;
the terminal voltage is less than the first voltage reference value in the third period comparison step; and
the terminal voltage is greater than the second voltage reference value is greater than the fourth period comparison step.

12. The moisture detection method by a moisture detection circuit for serial bus connectors according to claim 9,
wherein the moisture detection method is initiated based on a rising edge or falling edge of a signal provided by a host controller to the terminal of the serial bus connectors.
